(19) United States
(12) Patent Application Publication
(10) Pub. No.: US 2025/0111981 A1
(43) Pub. Date: Apr. 3, 2025

(54) Preparation Method for Power Module Component, and Power Module Component

(71) Applicants: HUIZHOU POCO NEW INDUCTOR TECHNOLOGY CO., LTD., Huizhou (CN); SHEN ZHEN JOVE ENTERPRISE LIMITED, ShenZhen (CN); POCO HOLDING CO., LTD., Shenzhen (CN); HUIZHOU POCO INDUSTRY CO., LTD., Huizhou (CN); HEYUAN POCO NEW MATERIAL CO., LTD., Heyuan (CN)

(72) Inventors: Tao Luo, Shenzhen (CN); Yunfan Zhang, Shenzhen (CN); Guojun Ye, ShenZhen (CN); Jiangming Ma, ShenZhen (CN); Xiongzhi Guo, ShenZhen (CN); Zhida Liu, ShenZhen (CN)

(73) Assignees: HUIZHOU POCO NEW INDUCTOR TECHNOLOGY CO., LTD., Huizhou (CN); SHEN ZHEN JOVE ENTERPRISE LIMITED, ShenZhen (CN); POCO HOLDING CO., LTD., Shenzhen (CN); HUIZHOU POCO INDUSTRY CO., LTD., Huizhou (CN); HEYUAN POCO NEW MATERIAL CO., LTD., Heyuan (CN)

(21) Appl. No.: 18/898,791

(22) Filed: Sep. 27, 2024

(30) Foreign Application Priority Data
Sep. 28, 2023 (CN) 202311283072.7

(51) Int. Cl. H01F 27/255; H01F 1/22; H01F 41/02

(52) U.S. Cl. CPC H01F 27/255; H01F 1/22; H01F 41/0246

(57) ABSTRACT

Provided are a preparation method for a power module component, and a power module component. The surface of the component is flat, which can improve the welding accuracy and reduce the contact resistance of the power module components, leading to a higher reliability. The circuits and pins are on the surface of the component, without additional volume, which reduces the volume of the component and improves the power density of the power module. In addition, the power module component provided by an example of the present application is prepared by integrated molding; the gaps among various elements are fully filled, so that the inductance and magnetic flux density of the product can be improved. Moreover, the power module component can have a very small volume, thus increasing the power density of the power module to make the power supply smaller in volume.

### CROSS-REFERENCE TO RELATED APPLICATIONS

This application claims priority to Chinese Patent Application No. 202311283072.7 filed Sep. 28, 2023, the disclosure of which is incorporated herein by reference in its entirety.

### TECHNICAL FIELD

The present application relates to the technical filed of power modules, in particular to a preparation method for a power module component, and a power module component.

### BACKGROUND

In recent years, with the development of data centers, artificial intelligence and other technologies, the central processing unit (CPU), graphics processing unit (GPU) and various types of integrated chips (ICs) have an increasingly fast working speed, an increasingly high integration degree, and an increasingly large working current, which requires improved power density, efficiency, and dynamic response form the voltage regulation module (VRM) of power supply module, greatly challenging the design of VRMs. In the voltage regulation module, the efficiency, power density, and frequency are getting higher and higher, the output inductor often accounts for the highest percentage in volume, and the selection of the inductor inductance also directly affects the efficiency and dynamic performance of the whole VRM.

The inductors used in existing power supply modules are usually ferrite air gap inductors pasted with external Pin needles or pressed inductors pasted with external Pin needles. The inductor is required to form a circuit by additionally pasting Pin needles after the molding, and the overall volume of the inductor will be increased by pasting Pin needles; the Pin needles are directly pasted to the magnet by glue, creating some gaps between the Pin needles and the magnet, which increases the volume of the inductor. In addition, the surface of the pin is likely to be uneven, which may affect the reliability of the circuit and the volume of the power module. Therefore, the existing method of pasting the Pin needles to power supply modules reduces the welding reliability and power density.

Therefore, it's an urgent problem for manufacturers to solve that the power supply modules have conventional Pin needles attachment, too large volume, low power density and poor welding reliability.

### SUMMARY

In order to solve the technical problems in the prior art, the present application provides a preparation method for a power module component, and a power module component, which can solve the technical problems of excessive power consumption, large volume, and low power density in the conventional ferrite air gap inductors used in the current power module.

In order to achieve the above technical effects, the present application provides the following technical solutions.

A first object of the present application is to provide a preparation method for a power module component, and the preparation method comprises: subjecting soft magnetic powder and a coil winding to compression molding to obtain an inductor blank; subjecting the inductor blank to heating and heat preservation treatment; forming a circuit layer on the surface of the inductor blank; and performing etching treatment on the circuit layer to form a desired circuit pattern and pins.

As a preferred technical solution of the present application, the etching treatment comprises: forming a photoresist layer on the circuit layer; and by using the photoresist layer as a reference, performing the etching treatment on the circuit layer to form the desired circuit.

As a preferred technical solution of the present application, the etching treatment comprises: forming a photoresist layer on the circuit layer; by using a mask as a reference, subjecting the photoresist layer to an exposure and development treatment to form a photoresist pattern; and by using the photoresist pattern as a reference, and performing the etching treatment on the circuit layer to form the desired circuit.

As a preferred technical solution of the present application, the compression molding is performed at a pressure of 5-24 T/cm2.

As a preferred technical solution of the present application, the heating and heat preservation is performed at a temperature of 150-850° C.

As a preferred technical solution of the present application, a method of forming the circuit layer on the surface of the inductor blank comprises laying metal on the surface of the inductor blank, and subjecting the metal to heating and/or pressing treatment to form the circuit layer.

As a preferred technical solution of the present application, the preparation method further comprises cleaning the inductor blank before the circuit layer is formed.

As a preferred technical solution of the present application, the preparation method further comprises subjecting the circuit layer to calendering treatment.

As a preferred technical solution of the present application, the preparation method further comprises removing the photoresist layer after the etching treatment.

A second object of the present application is to provide a power module component, and the power module component is prepared by the preparation method for a power module component provided in the first object. The power module component comprises an inductor blank and a circuit located on the surface of the inductor blank.

Compared with the prior art, the present application at least has the following beneficial effects:
(1) the present application provides a preparation method for a power module component, and a power module component, wherein in the preparation method, the surfaces of the circuit and the pins formed by the processes of exposure, development, and etching are flat, thereby improving the precision and reducing the contact resistance of the power module component, so as to achieve the effect of reducing the loss of the power module component;
(2) the present application provides a preparation method for a power module component, and a power module component, wherein the power module component is prepared by integral molding; the gaps among various elements are fully filled, so that the inductance and magnetic flux density of the product can be improved, further achieving the effect of reducing the loss; and
(3) the present application provides a preparation method for a power module component, and a power module component, wherein the power module component has a small volume, so the power density of the power module component can be improved, thereby achieving the effect of reducing power consumption and volume, and the technical problems of large volume, low power density and poor reliability of the current power supply module adopting the conventional pasted Pin are solved.

### BRIEF DESCRIPTION OF THE DRAWINGS

FIG. 1 shows a flow chart of a preparation method for a power module component provided by an example of the present application.

FIG. 2 shows a first sub-flow chart of a preparation method for a power module component provided by an example of the present application.

FIG. 3 shows a second sub-flow chart of a preparation method for a power module component provided by an example of the present application.

FIG. 4 shows a third sub-flow chart of a preparation method for a power module component provided by an example of the present application.

FIG. 5 shows a fourth sub-flow chart of a preparation method for a power module component provided by an example of the present application.

FIG. 6 shows a second flow chart of a preparation method for a power module component provided by an example of the present application.

FIG. 7 is a structural schematic diagram of a power module component provided by an example of the present application.

Reference list: 200—power module component, 201—bare inductor, and 202—circuit pattern.

The present application is described in further detail below. However, the following examples are only simple examples of the present application, and do not represent or limit the protection scope of the claims of the present application. The protection scope of the present application is subject to the claims.

### DETAILED DESCRIPTION

The technical solutions in examples of the present application will be described clearly and completely below in conjunction with the accompanying drawings in examples of the present application. Obviously, the described examples are only a part of the examples of the present application, and not all of the examples. Based on the examples of the present application, other examples obtained by those skilled in the art without creative efforts shall all fall within the protection scope of the present application.

In addition, the terms such as “first” and “second” in the specification and claims of the present application are used to identify different objects but not to describe a particular order. The terms “comprise” and “have”, and any variations thereof are intended to be non-exclusive.

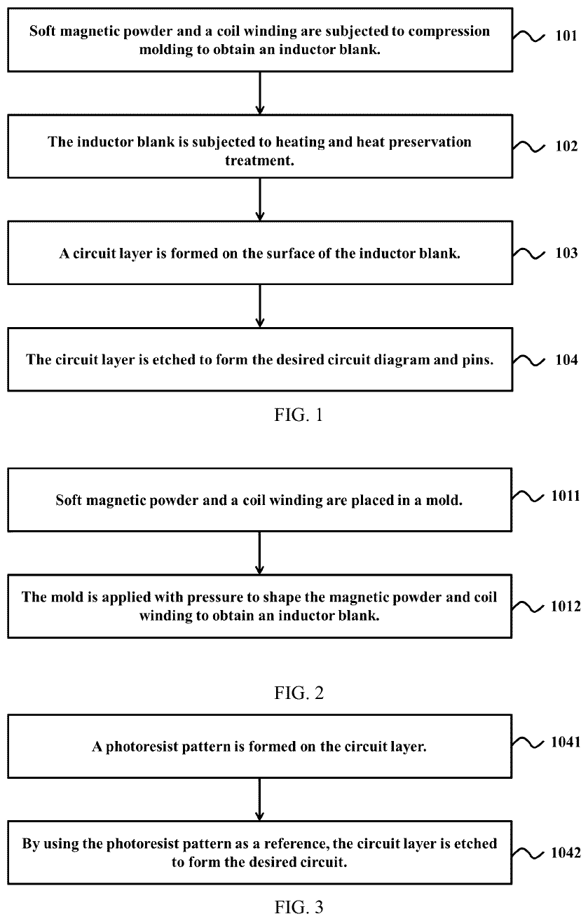

Examples of the present application provide a preparation method for a power module component, referring to FIG. 1. FIG. 1 shows a flow chart of a preparation method for a power module component provided by an example of the present application. As shown in FIG. 1, the preparation method for a power module component provided by an example of the present application comprises the following specific steps.

Step 101: soft magnetic powder and a coil winding are subjected to compression molding to obtain an inductor blank.

It should be noted that the soft magnetic powder can be one or a mixture of at least two of iron-based or iron-containing alloy magnetic powder (such as Fe, Fe—Si, Fe—Ni, Fe—Si—Cr, Fe—Si—Al, and Fe—Ni—Mo), Fe-based amorphous magnetic powder, or nanocrystalline magnetic powder. The surface of the powder has an insulation layer, and a material of the insulation layer has a high resistivity and toughness to ensure that the powder particles are not completely in contact with each other to reduce the eddy current between the magnetic powder particles and to improve the insulation resistance value; meanwhile, the insulation material has a certain bonding characteristics to improve the strength of the inductor blank.

Step 102: the inductor blank is placed in a heat treatment furnace, and subjected to heating and heat preservation.

It should be noted that the inductor blank is placed in a heat treatment furnace for heating and heat preservation, so that the residual stress caused by the molding process introduced into the inductor blank can be released, and the bare inductor component having the desired electromagnetic properties can be prepared.

Step 103: a circuit layer is formed on the surface of the bare inductor.

It should be noted that the copper foil is laid on the surface of the bare inductor, and adhered to the bare inductor closely by heating or pressing method so as to form the circuit layer. Other conductive materials can also be used to form the circuit layer, which is not particularly limited in the examples of the present application.

Step 104: the circuit layer is processed to form a desired circuit and pins.

It should be noted that the circuit and pins are paths for connecting the power module component to other power module components, i.e., the Pin needles provided on the inductors in the prior art.

Referring to FIG. 2, FIG. 2 shows a first sub-flow chart of a preparation method for a power module component provided by an example of the present application. As shown in FIG. 2, step 101 comprises the following specific steps.

Step 1011, soft magnetic powder and a coil winding are placed in a mold.

Step 1012, the mold is applied with pressure to shape the magnetic powder and coil winding to obtain an inductor blank.

It should be noted that the compression molding is adopted in the present application, and the compression molding is performed with a pressure of 5-24 T/cm², such as 5 T/cm², 6 T/cm², 7 T/cm², 8 T/cm², 9 T/cm², 10 T/cm², 11 T/cm², 12 T/cm², 13 T/cm², 14 T/cm², 15 T/cm², 16 T/cm², 17 T/cm², 18 T/cm², 19 T/cm², 20 T/cm², 21 T/cm², 22 T/cm², 23 T/cm², or 24 T/cm², as well as any value between any two end points; the pressure is preferable to be higher. It should be noted that the appropriate increase of pressure can increase the density of the magnetic part to increase the magnetic permeability, but the excessive pressure has the risk of reducing the insulation characteristic of the inductor, especially for the spiral coil having more than 1 turn. In addition, when the pressure is increased to a certain level, the density of the magnetic part tends to be stable, and will not continue to increase. Too much pressure is harmful to economic efficiency; too low pressure can lead to poor inductance strength and low magnetic permeability, and electromagnetic properties cannot meet the demand.

The compression molding causes elastic deformation and plastic deformation of the soft magnetic powder, so it is necessary to perform annealing treatment on the inductor blanks to remove the internal stress. Meanwhile, the annealing can also eliminate the internal defects in the powder caused by the powder preparation process. Therefore, the annealing can improve the initial magnetic permeability of the magnetic part, reduce the iron core loss, and improve the mechanical strength of the inductive component. Based on the different types of the soft magnetic powder, a temperature of the heating and heat preservation is generally within 150-850° C., such as 150° C., 200° C., 250° C., 300° C., 350° C., 400° C., 450° C., 500° C., 550° C., 600° C., 650° C., 700° C., 750° C., 800° C., or 850° C., as well as any value between any two end points. If the annealing temperature is too low, it is not enough to release the internal residual stress, resulting in a low magnetic permeability and high loss; if the annealing temperature is too high, it will lead to the damage of the insulation layer on the surface of the powder, resulting in a reduced initial magnetic permeability and increased eddy current loss on the contrary.

Referring to FIG. 3, FIG. 3 shows a second sub-flow chart of a preparation method for a power module component provided by an example of the present application. As shown in FIG. 3, step 104 comprises the following specific steps.

Step 1041, a photoresist pattern is formed on the circuit layer.

Step 1042, by using the photoresist pattern as a reference, the circuit layer is etched to form a desired circuit.

It should be noted that when the etching treatment is performed, the etching solution will etch away the circuit layer while the photoresist pattern cannot be eroded. Therefore, when the etching process is performed, the circuit layer located under the photoresist pattern will be reserved, and the circuit layer located in the other portions will be eroded away, thereby forming a circuit consistent with the photoresist pattern.

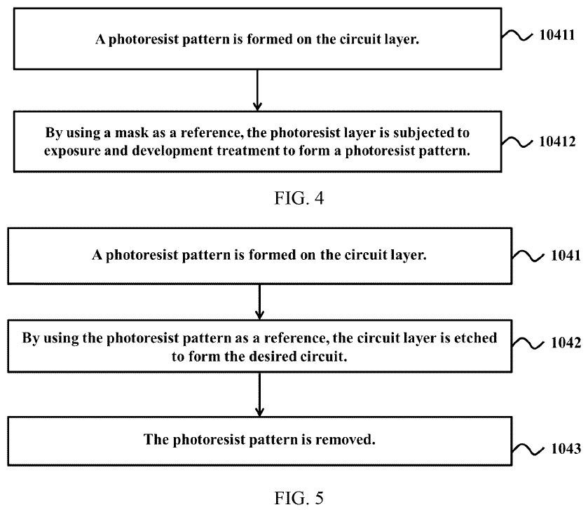

Referring to FIG. 4, FIG. 4 shows a third sub-flow chart of a preparation method for a power module component provided by an example embodiment of the present application. As shown in FIG. 4, step 1041 comprises the following specific steps.

Step 10411, a photoresist layer is formed on the circuit layer.

It should be noted that the photoresist layer is formed by using a photoresist attached to the whole surface of the circuit layer.

It should be noted that the photoresist layer is made of a positive photoresist material or a negative photoresist material. The material for the photoresist layer is selected according to the mask used in the exposure and development process.

Step 10412, by using a mask as a reference, the photoresist layer is subjected to an exposure and development process to form a photoresist pattern.

Referring to FIG. 5, FIG. 5 shows a fourth sub-flow chart of a preparation method for a power module component provided by an example of the present application. As shown in FIG. 5, step 104 comprises the following specific steps:

Step 1041, a photoresist pattern is formed on the circuit layer.

Step 1042, by using the photoresist pattern as a reference, the circuit layer is etched to form a desired circuit.

Step 1043, the photoresist pattern is removed.

It should be noted that because the photoresist pattern is provided to form the desired circuit pattern, it will affect the performance of the power module component. Therefore, it is necessary to remove the photoresist pattern after the desired circuit is formed so as to avoid affecting the performance of the power module component.

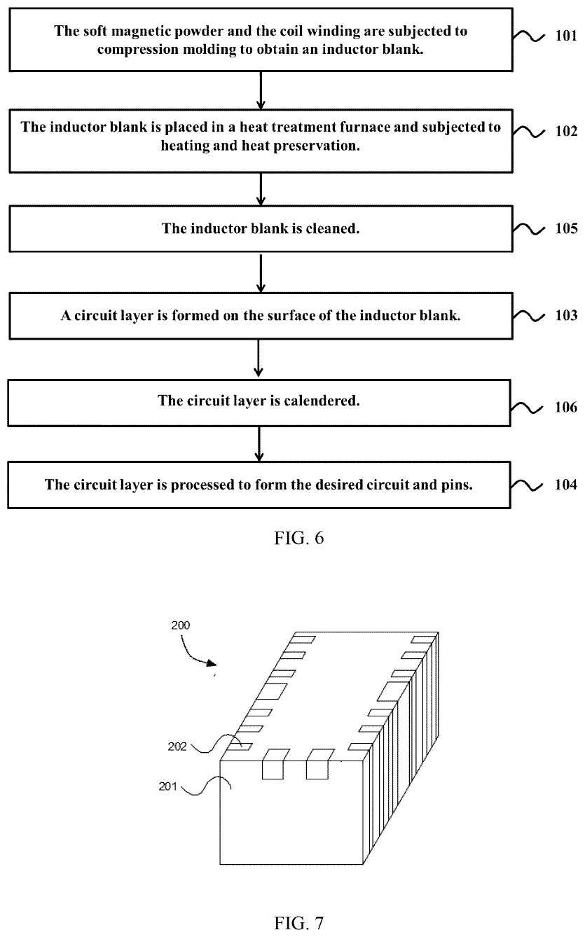

Referring to FIG. 6, FIG. 6 shows a second flow chart of a preparation method for a power module component provided by an example of the present application. As shown in FIG. 6, the preparation method for a power module component provided by an example of the present application comprises the following specific steps.

Step 101, the soft magnetic powder and the coil winding are subjected to compression molding to obtain an inductor blank.

Step 102, the inductor blank is placed in a heat treatment furnace and subjected to heating and heat preservation.

Step 105, the bare inductor is cleaned.

It should be noted that if the surface of the inductor blank has contaminants, the circuit layer formed in the subsequent process will be uneven, thus affecting the power consumption of the power module components. Therefore, the inductor blank is cleaned to remove contaminants such as grease or dirt from the surface of the inductor blank, thereby avoiding the increase of power consumption of the power module component due to the unevenness of the circuit layer formed in the subsequent process.

It should be noted that the inductor blanks can be placed in a washing machine for cleaning, or the inductor blanks can be cleaned in other ways, which is not particularly limited in the examples of the present application.

Step 103, a circuit layer is formed on the surface of the bare inductor.

Step 106, the circuit layer is calendered.

It should be noted that the circuit layer is calendered with a calender, which ensures that the circuit layer is flat and has no bubbles, thus helps to improve the flatness of the circuit pattern formed in the subsequent process and improve the reliability of the power module component.

Step 104, the circuit layer is processed to form the desired circuit and pins.

In the preparation method for a power module component provided by an example of the present application, the circuit pattern is formed by the processes of exposure, development, and etching. Flatting the surface of the component improves the precision and reduces the contact resistance of the power module component, so as to achieve the effect of reducing the loss of the power module component. In addition, the power module component which uses the preparation method for a power module component provided by an example of the present application is prepared by integrated molding; the gaps among various elements are fully filled, so that the inductance and magnetic flux density of the product can be improved, thereby achieving the effect of reducing the loss. Moreover, the power module component which uses the preparation method for a power module component provided by an example of the present application can have a very small volume, thus increasing the power density of the power module to make the power supply smaller in volume.

Examples of the present application also provide a power module component; refer to FIG. 7. FIG. 7 shows a structural schematic diagram of a power module component provided by an example of the present application. As shown in FIG. 7, the power module component 200 provided by the example of the present application comprises a bare inductor 201 and a circuit pattern 202 located on the surface of the bare inductor 201. The power module component 200 is prepared by the preparation method for the power module component as described above, and the preparation method for the power module component can be referred to the above description and will not be repeated herein.

In the preparation method for a power module component and the power module component provided in examples of the present application, the circuit is formed by the processes of exposure, development, and etching, so that the inductor is tightly bonded to the circuit and the pins of the circuit, which reduces the size; the surface of the component is flat, thereby improving the precision and reducing the contact resistance of the power module component, so as to achieve the effect of reducing the loss of the power module component. In addition, the power module component which uses the preparation method for a power module component provided by an example of the present application is prepared by integrated molding; the gaps among various elements are fully filled, so that the inductance and magnetic flux density of the product can be improved, thereby achieve the effect of reducing the loss. Moreover, the power module component which uses the preparation method for a power module component provided by an example of the present application can have a very small volume, thus increasing the power density of the power module to make the power supply smaller in volume.

The preparation method for a power module component and the power module component provided by the examples of the present application are described in detail above, and specific examples are used herein to illustrate the principles and implementations of the present application, and the description of the above examples is only used to assist in the understanding of the method of the present application and the key ideas thereof. Meanwhile, for those skilled in the field, according to the idea of the present application, there will be changes in the specific embodiments and the application scope; in view of the above, the contents of this specification should not be regarded as a limitation of the present application.

What is claimed is:

1. A preparation method for a power module component, which comprises:
subjecting soft magnetic powder and a coil winding to compression molding to obtain an inductor blank;
subjecting the inductor blank to heating and heat preservation treatment;
forming a circuit layer on the surface of the inductor blank; and
performing etching treatment on the circuit layer to form a desired circuit and pins.

2. The preparation method according to claim 1, wherein the etching treatment comprises:
forming a photoresist layer on the circuit layer; and
by using the photoresist layer as a reference, performing the etching treatment on the circuit layer to form a desired circuit.

3. The preparation method according to claim 2, wherein the etching treatment comprises:
forming the photoresist layer on the circuit layer;
by using a mask as a reference, subjecting the photoresist layer to an exposure and development treatment to form a photoresist pattern; and
by using the photoresist pattern as a reference, performing the etching treatment on the circuit layer to form the desired circuit.

4. The preparation method according to claim 1, wherein the compression molding is performed at a pressure of 5-24 T/cm².

5. The preparation method according to claim 1, wherein the heating and heat preservation treatment is performed at a temperature of 150-850° C.

6. The preparation method according to claim 1, wherein a method of forming the circuit layer on the surface of the inductor blank comprises laying metal on the surface of the inductor blank, and subjecting the metal to heating and/or pressing treatment to form the circuit layer.

7. The preparation method according to claim 1, wherein the preparation method further comprises cleaning the inductor blank before the circuit layer is formed.

8. The preparation method according to claim 1, wherein the preparation method further comprises subjecting the circuit layer to calendering treatment.

9. The preparation method according to claim 2, wherein the preparation method further comprises removing the photoresist layer after the etching treatment.

10. A power module component, which is prepared by the preparation method for a power module component according to claim 1, and comprises an inductor blank and a circuit located on the surface of the inductor blank.
